(19) United States
(12) Patent Application Publication
(10) Pub. No.: US 2022/0130946 A1
(43) Pub. Date: Apr. 28, 2022

(54) OLED Display Design for Local Transparency

(71) Applicant: Universal Display Corporation, Ewing, NJ (US)

(72) Inventors: Michael HACK, Carmel, CA (US); Michael Stuart WEAVER, Princeton, NJ (US)

(21) Appl. No.: 17/452,135

(22) Filed: Oct. 25, 2021

Related U.S. Application Data
(60) Provisional application No. 63/105,835, filed on Oct. 26, 2020.

(51) Int. Cl. H01L 27/32; H01L 51/52

(52) U.S. Cl. CPC H01L 27/3288; H01L 51/5281; H01L 27/3234

(57) ABSTRACT

New and/or improved techniques and arrangements are provided to increase the overall transparency of a local region within the display itself based on arrangements of backplane and/or frontplane architectures.

### CROSS-REFERENCE TO RELATED APPLICATIONS

This application claims the priority benefit of U.S. Provisional Patent Application Ser. No. 63/105,835, filed Oct. 26, 2020, the entire contents of which are incorporated herein by reference.

### FIELD

The present invention relates to devices and techniques for fabricating organic emissive devices, such as organic light emitting diodes, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-S00 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-S00 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.3731, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

In an embodiment, a display panel is provided that includes a backplane having at least two portions with different levels of transparency. An OLED stack may be disposed over the backplane, thereby allowing for a combined device that has different levels of transparency in different regions of the display.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an example layout according to embodiments disclosed herein, which allows for one section of an AMOLED display (for example, above the cameras/sensors) to be driven as a passive matrix display to increase transparency including a dedicated passive matrix (PM) shift register/scan driver and a passive matrix data driver chip to provide current sourcing for PM drive.

FIG. 4 shows an example TFT pixel circuit for passive matrix subpixels such as shown in FIG. 3 to enable the full display to use a common unpatterned cathode.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

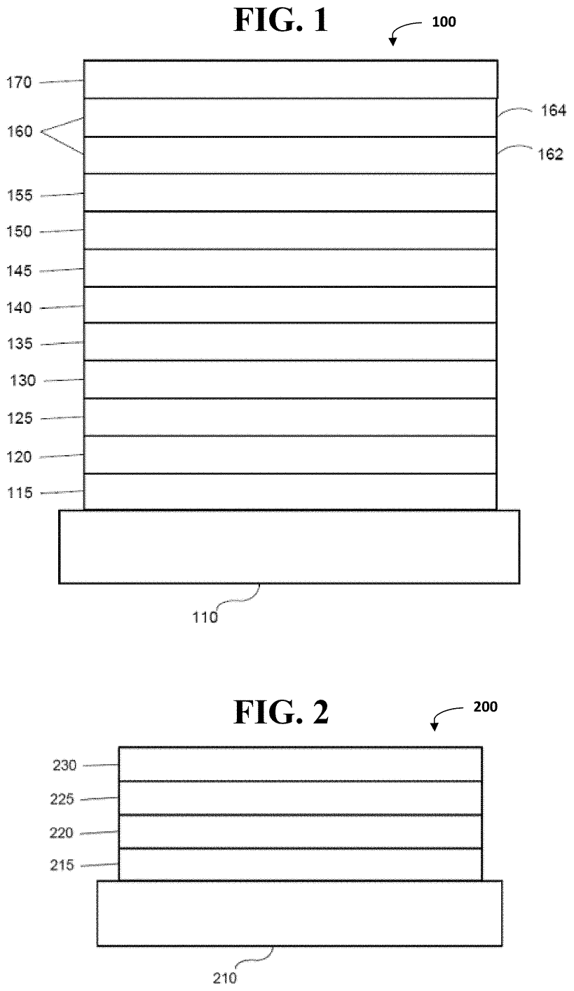

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light, which may be altered by another layer such as a color filter or other color altering layer that does not itself emit an initial light within the device, but may re-emit altered light of a different spectra content based upon initial light emitted by the emissive layer.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Recent devices that use OLED-based displays, such as cell phones, tablets, portable display panels, and the like, are increasingly being designed with cameras and other (optical) sensing components placed under the display as opposed to in a notch cut out of the display area. Compared to prior arrangements, this allows for maximization of the display fill-factor, i.e., the ratio of the display active-area to the front area of the device itself.

Several approaches have been implemented to increase the transparency of the OLED frontplane. For example, a transparent cathode may be employed. As another example, the display resolution may be lowered over the area above the camera or other sensor. For example, the number of pixels may be reduced such that the pixels are more spaced apart, or different pixel sizes may be used. Embodiments disclosed herein provide new and/or improved techniques and arrangements to increase the overall transparency of a local region within the display itself, by considering both backplane and/or frontplane architectures. Each approach may be used alone or in combination with other techniques disclosed herein, as well as prior techniques such as transparent electrodes and modified display resolution(s).

Embodiments disclosed herein may be particularly well-suited to increasing the transparency of a relatively small region of a display, for example 5 mm×5 mm, 10 mm×10 mm, or any intervening range, or functionally large enough to cover one or more cameras and any sensors or other components, such as a flash or other optical component, that may be incorporated into a device and be able to see through the device and which may be placed underneath the display so the aperture ratio of the display to device surface area can be close to 100%. In some cases, the more transparent region of the display may include a relatively small portion of the backplane and/or the total active area of the display, such as less than 1%, less than 0.5%, or less than 0.25%. Generally, embodiments disclosed herein use a backplane that has one region that is more transparent than the other. For example, a first region of the backplane, which may include the majority of the backplane, may be a conventional OLED backplane. A second region of the backplane which corresponds to the placement of a camera or other similar optical components in the resulting display device, may have a higher transparency than the first portion. One or more techniques disclosed herein may be used in any combination to achieve the desired level of transparency in the second region of the backplane. The more transparent region may have a uniform transparency, or it may be more transparent in certain regions. For example, the region immediately in line with the camera or other optical components may be the most transparent within the more transparent second region of the display, which other portions of the second region may have a transparency between that of the first region and the most transparent portion of the second region. The second, more transparent region may have a uniform transparency or an average transparency of at least 40%, 50%, 60%, 70%, 80%, 90%, or any intervening value.

In an embodiment, the line width of metal lines in the backplane of the pixels covering the optical elements that need improved transparency may be reduced. This approach may include power lines, data lines, scan lines, and any other conducting lines required to connect pixels with external connections to the backplane or display. This may increase line resistances, but such increase may be acceptable to overall device design and performance, especially because it will only apply for a few mm of a line that may be 10 cm or longer. Accordingly, the reduced line width will only have a small overall effect on total line resistance.

In an embodiment, transparent conductors may be used for portions of pixels disposed above the camera and/or other optical devices as a replacement for opaque metals. For example, conductors may be formed from ITO, IZO, similar materials, or combinations thereof.

In an embodiment, the circular polarizer may be omitted from the region above the optical components. Typically this region is reasonably transparent and any increased reflection resulting from omission of the polarizer should be minimal.

In an embodiment, two or more cameras may be disposed below the display panel. Such an arrangement may image quality by taking two different images simultaneously from different positions to improve correction based on removing artifacts resulting from objects blocking the optical path of each camera.

In an embodiment, the resolution of blue sub-pixels in the region of the display above the optical components may be reduced. The human eye is less sensitive to the special resolution of blue light due to the low density of S cones on the retina, so such an arrangement may be used with little or no observable effect. The additional space gained by decreasing the density of blue sub-pixels may be used to provide increased transparency and/or to increase the fill-factor of red and green sub-pixels so that their voltage is reduced and their lifetime can be increased. This may compensate for increased voltage associated with passive matrix driving techniques as disclosed herein.

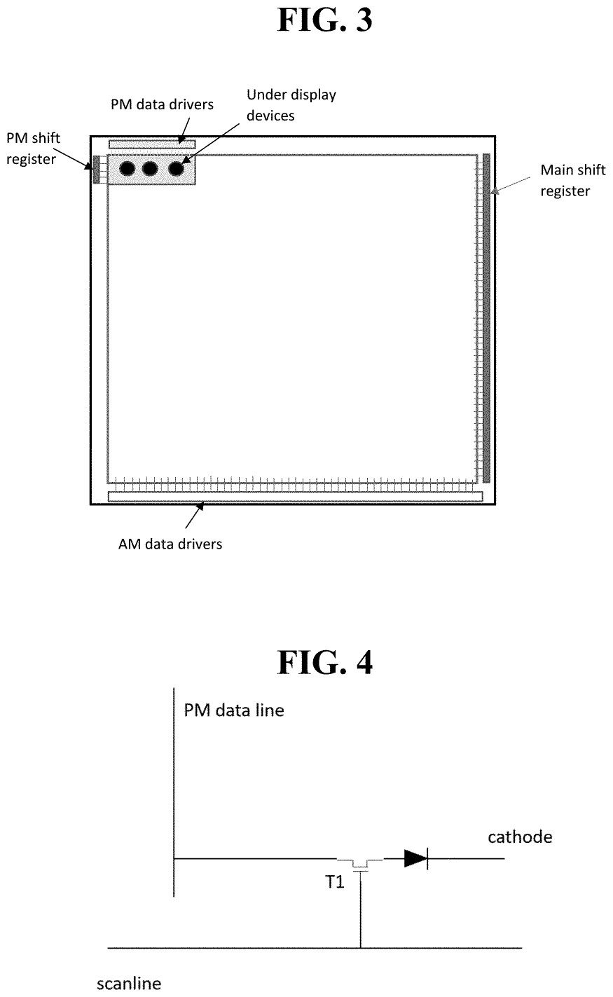

In an embodiment, the more transparent region of the display may be driven as a passive matrix display so as to remove most of the transistors from the backplane in this region compared to active drive techniques. As most sub-pixel circuits to drive OLEDs have multiple TFT circuits often using six or seven TFTs, and there are 3 sub-pixels per pixel, using a one TFT passive matrix approach per sub-pixel could save nearly 20 TFTs per pixel which will significantly improve display transparency. Such an arrangement can be reasonably implemented in a small local region of the display, for example as shown in FIG. 3.

Passive matrix addressing works by selecting a pixel using scan lines, assuming N scan lines, and driving each subpixel with a current N times the current it would require for steady-state operation as in active matrix addressing, for just the period that the subpixel is being addressed. So the overall brightness to the eye is the same as in an active matrix display, but the OLEDs are effectively being pulsed N times the current for 1/N period of time. Typically such an arrangement can be implemented for small size displays with about 200 or fewer scan lines, as this passive matrix architecture is much less power efficient than an active matrix drive.

In a conventional passive matrix display each OLED subpixel is addressed by using a row/scan line on one side of the OLED and a patterned cathode (in stripes or lines) on the other side. In an active matrix display the cathode is usually electrically continuous across the display, with no patterning. In an embodiment as disclosed herein, an addressing scheme shown in FIG. 4 may be used in which one TFT in each subpixel is used as the addressing element for each OLED in conjunction with an unpatterned electrically continuous cathode. In this case the OLED will be current driven while the subpixel is addressed.

To avoid the number of scan lines N for the passive matrix region being too high, a separate driving scheme may be used for only the small passive matrix (PM) transparent region, using a dedicated current driven data chip and a second PM scan driver. The scan driver may be integrated into the display and a small second current data driver chip to provide PM data drivers can be placed on, or attached to, the display substrate near to the transparent region, as shown in FIG. 3. This approach uses a relatively low N. For example, if a cell phone has a 500 dpi resolution and the region over the camera is about 5 mm (0.2 in), the region includes 100 pixels and therefore N=100 for the region.

The PM and active matrix (AM) sections of the display require different drive signals from the two different driver chips because the AM portion generally is voltage driven, while PM pixels generally are current driven. As shown in FIG. 3, the PM region may be disposed over the optical components at one corner of the overall display. This allows the PM region to be directly connected to the associated dedicated data chip and scan drivers. The data lines and scan lines driving the AM portion of the rest of the display may terminate at the edge of the PM region.

If the PM region, or a portion of the PM region corresponding to the location of a camera or other sensor, is not placed in one of the display corners, but more in the center of the display, then additional data and scanlines may be used to connect the PM pixels to their dedicated PM scan driver and PM data drivers, while allowing the existing AM data and scan signals to propagate through the display to AM pixels to be driven on the other side of the PM display region away from the scan and data drivers.

Generally in a display panel, mobile display, or other device, an OLED stack is disposed above the backplane, which provides control of the OLED stack to produce illumination and/or image display. In some embodiments, a uniform OLED stack may be disposed over all portions of the backplane, i.e., over the more transparent and less transparent region(s) of the backplane. The OLED stack may be continuous or patterned; in a patterned uniform arrangement, the pattern may be the same over both regions of the backplane. In other embodiments, different OLED stacks and/or pixel or sub-pixel arrangements may be used. For example, a different OLED stack may be used in the more transparent region(s) than in the less transparent region(s), which may include different layers, materials, thicknesses, or combinations thereof. In some embodiments, different electrodes may be used in each region, in addition to, or instead of different arrangements of organic layers. Alternatively or in addition, different patterns of pixels and/or sub-pixels may be used in each region, such as previously disclosed herein.

The transparent region of the display may result in different device optics in the region. Driving the transparent region using a PM driving scheme also typically will result in a different grey scale look up table being required than in the AM portion of the display. The higher temporal luminance required from the PM OLEDs may also change the recombination zone position within the device relative to the AMOLEDs, which also may cause distortion in the color observed from the PM pixels relative to the AM pixels.

Any such color differences associated with these effects may be mitigated through various arrangements and techniques. For example, different look-up stable may be used for the transparent region of the display than those used for the rest of the display for grey scale, CIE, luminance and/or luminance values, thereby directly compensating for the difference in color that would result if the same values were used for both AM and PM pixels.

As another example, optical cavity lengths may be used to compensate for color differences. A standard OLED MP panel typically is fabricated using 5-6 fine metal mask (FMM) steps. For example, different masks may be used to deposit the red, green, and blue (R, G, B) EMLs, as well as associated R′, G′, and B′ prime layers which typically are EBLs, though they may be or include HILs and/or HTLs. Generally prime layer thicknesses may be chosen to separately optimize the R, G and B sub-pixel cavity lengths.

In embodiments disclosed herein, in the transparent region, the prime layers of each respective sub-pixel may be deposited onto a different colored sub-pixel. For example, when the G′ prime layer is deposited, it may cover both the R and G sub-pixels within the transparent region of the display. This would provide the R sub-pixel in the transparent region with a longer cavity length than in the standard display region. As another example, the cavity lengths as defined by the prime masks in the transparent region may be R′, G′, B′ (as in the standard display areas) plus other options such as R′+G′, R′+B′, B′+G′, R′+G′+B′, and no prime layer, or various other combinations. In this way the cavity length in the transparent region may be manipulated without adding additional manufacturing steps or additional cost or complexity. Other layers also may be manipulated in the same way, such as varying the thickness of HTL ETL, HIL, HBL, CPL, and/or various combinations thereof for different pixels. More generally, the thickness and number of depositions within the transparent region of the display may vary from those in the conventional region of the display to allow for compensation of optical effects that would otherwise result.

Other techniques may be used to compensate for potential optical effects resulting from the increased transparency of the more transparent region of the display, though they may be less preferred due to cost and/or complexity considerations. For example, different cavity lengths may be patterned in the transparent region. In this arrangement, different thicknesses of various layers may be used to fabricated sub-pixels in the more transparent region. For example, different cavity thicknesses may be used for the R, G, and/or B sub-pixels to compensate for color shift resulting from other arrangements of the backplane and device. As another example, different materials may be used in the transparent region than in the rest of the display, such as where emitters having different emission spectra are used. The resulting total emission thus may be uniform across the display due to the interaction of the different emission profiles with the optical effects caused by other changes made to the device relative to a conventional display device.

In some embodiments, multiple transparent regions may be used. For example, it may be desired to have two or more cameras, sensors, flash components, or other optical components arranged in different areas of the device, such as in opposing corners, across one edge of the display, or the like, where it is desirable to have these components placed under the display and receive light from above the display. In such a device, one or more techniques disclosed herein may be used for each transparent region. The same techniques or different techniques or combinations of techniques may be used for each transparent region. The transparent regions may have the same or different transparencies, and they may be selected to match the optical components arranged in a stack with the transparent regions. For example, a very sensitive visible spectrum camera may have different transparency requirements in degree and/or wavelength compared to an IR sensor, flash, or other optical component.

Transparent regions of a backplane and display panel as disclosed herein may be disposed at any desired location of a display panel. Common locations may be one or more corners of the display panel, near one or more edges, near the center, or combinations thereof. In some cases it may be desirable for the transparent region to be in the middle region of the display panel, such that it is not immediately adjacent to any edge of the display panel, i.e., so that the transparent region does not extend to an edge of the display. In other arrangements, the transparent region may extend to one or more edges of the display panel.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A display panel comprising:
a backplane having a first portion and a second portion, the second portion having a higher uniform transparency or higher average transparency than the first portion; and
an organic light emitting diode (OLED) stack disposed over the backplane.

2. The display panel of claim 1, wherein the second portion includes not more than a 25 mm² region of the backplane.

3. The display panel of claim 1, wherein the second portion includes not more than 1% of the backplane.

4. The display panel of claim 1, wherein portions of conductive traces in the second portion of the backplane are thinner than portions of the conductive traces in the first portion of the backplane, the conductive traces comprising one or more lines selected from a group consisting of: power lines, data lines, scan lines, or a combination thereof.

5. (canceled)

6. The display panel of claim 1, wherein portions of conductive traces in the second portion of the backplane comprise one or more transparent metals, other conductive materials, or a combination thereof.

7. (canceled)

8. The display panel of claim 1, further comprising one or more cameras disposed below the second portion of the backplane.

9. (canceled)

10. The display panel of claim 1, further comprising a circular polarizer disposed over only the first portion of the backplane.

11. The display panel of claim 1, wherein a resolution or fill-factor of one or more types of sub-pixels is lower in a portion of the OLED layer disposed over the second portion of the backplane.

12. (canceled)

13. The display panel of claim 1, wherein the second portion of the backplane is configured as a passive matrix backplane.

14. (canceled)

15. The display panel of claim 13, wherein the second portion of the backplane comprises not more than one thin film transistor (TFT) per sub-pixel, and/or the display panel is configured to provide separate drive signals to the first portion of the backplane and the second portion of the backplane.

16. The display panel of claim 15, wherein the second portion of the backplane is directly connected to a dedicated driving system separate from a driving system of the first portion of the backplane.

17. The display panel of claim 15, wherein data lines and scan lines for the second portion of the backplane terminate at an edge of the second portion of the backplane.

18. The display panel of claim 1, wherein the second portion of the backplane is disposed at a corner of the display panel.

19. The display panel of claim 1, wherein the backplane comprises a third portion having a higher transparency than the first portion.

20. The display panel of claim 19, further comprising a camera disposed below at least one of the second portion of the backplane and the third portion of the backplane.

21. The display panel of claim 1, wherein the second portion of the backplane is not immediately adjacent to any edge of the display panel.

22. The display panel of claim 1, wherein a portion of the OLED stack in the first region is different than a portion of the OLED stack in the second region.

23. The display panel of claim 1, wherein the anode, the cathode, or a combination thereof in the first region is different from the corresponding anode, cathode, or combination thereof in the second region.

24. A consumer electronic device comprising the display panel of claim 1.

25. The consumer electronic device of claim 24, wherein the device is at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign.
